(19) United States
(12) Patent Application Publication
(10) Pub. No.: US 2026/0290430 A1
(43) Pub. Date: Sep. 24, 2026

(54) MEMORY DEVICE

(71) Applicant: Kioxia Corporation, Tokyo (JP)

(72) Inventors: Takashi INUKAI, Yokkaichi (JP); Yuto IURA, Yokkaichi (JP); Takayuki MIYAZAKI, Yokkaichi (JP); Tomone SASAKI, Yokkaichi (JP)

(73) Assignee: Kioxia Corporation, Tokyo (JP)

(21) Appl. No.: 19/312,155

(22) Filed: Aug. 27, 2025

(30) Foreign Application Priority Data
Mar. 24, 2025 (JP) 2025-048732

(51) Int. Cl. G11C 11/4091; G11C 5/06; G11C 5/10

(52) U.S. Cl. CPC G11C 11/4091; G11C 5/063; G11C 5/10

(57) ABSTRACT

A sense amplifier circuit has first and second inputs. The transistors supply a first potential to the first and second inputs based on a first signal. A first memory cell includes a first cell transistor. A first selection transistor is coupled between the first input and the first memory cell. A second selection transistor is coupled between the second input and a second memory cell. A first operation of raising a potential of a gate of the first selection transistor is performed. A second operation of lowering a potential of the first signal is performed after the first operation. A third operation of raising a potential of a gate of the first cell transistor and raising a potential of a gate of the second selection transistor is performed after the second operation.

### CROSS-REFERENCE TO RELATED APPLICATIONS

This application is based upon and claims the benefit of priority from Japanese Patent Application No. 2025-48732, filed Mar. 24, 2025, the entire contents of which are incorporated herein by reference.

### FIELD

Embodiments described herein relate generally to a memory device.

### BACKGROUND

A dynamic random access memory (DRAM) is known as a memory device. The memory cell of the DRAM includes a capacitor and a transistor. The memory cell holds data based on the charge accumulated in the capacitor. The voltage based on the data of the memory cell from which the data is read is amplified by the sense amplifier, whereby the stored data is determined.

### BRIEF DESCRIPTION OF THE DRAWINGS

FIG. 1 illustrates functional blocks and related components of a memory device according to a first embodiment.

FIG. 2 illustrates some components of the memory device of the first embodiment and coupling of the components.

FIG. 3 illustrates some components and coupling of the components of the sense amplifier of the memory device of the first embodiment.

FIG. 4 illustrates some components and coupling of the components during data reading of the memory device of the first embodiment.

FIG. 5 illustrates several states during data reading of the memory device of the first embodiment along time.

FIG. 6 illustrates potentials of several interconnects and signals during data reading of the memory device of the first embodiment along time.

FIG. 7 illustrates some components and coupling of the components of a memory device according to a first modification of the first embodiment.

FIG. 8 illustrates a state of the memory device according to the first modification of the first embodiment during data reading.

FIG. 9 illustrates potentials of several interconnects and signals during data reading of the memory device according to the first modification of the first embodiment along time.

FIG. 10 illustrates potentials of several interconnects and signals during data reading of a memory device according to a second modification of the first embodiment along time.

FIG. 11 illustrates some components and coupling of the components during data reading of a memory device according to a third modification of the first embodiment.

FIG. 12 illustrates potentials of several interconnects and signals during data reading of the memory device according to the third modification of the first embodiment along time.

FIG. 13 illustrates some components and coupling of the components during data reading of a memory device of a second embodiment.

FIG. 14 illustrates potentials of several interconnects and signals during data reading of the memory device of the second embodiment along time.

FIG. 15 illustrates potentials of several interconnects and signals during data reading of a memory device according to a first modification of the second embodiment along time.

FIG. 16 illustrates potentials of several interconnects and signals during data reading of a memory device according to a second modification of the second embodiment along time.

FIG. 17 illustrates some components and coupling of the components during data reading of a memory device according to a third modification of the second embodiment.

FIG. 18 illustrates potentials of several interconnects and signals during data reading of the memory device according to the third modification of the second embodiment along time.

FIG. 19 illustrates potentials of several interconnects and signals during data reading of a memory device according to a third embodiment along time.

FIG. 20 illustrates potentials of several interconnects and signals during data reading of a memory device according to a first modification of the third embodiment along time.

### DETAILED DESCRIPTION

In general, according to one embodiment, a memory device includes a sense amplifier circuit, a plurality of transistors, a first interconnect, a second interconnect, a first memory cell, a first selection transistor, a second memory cell, and a second selection transistor. The sense amplifier circuit has a first input and a second input. The transistors supply a first potential to the first input and the second input based on a first signal. The first interconnect is coupled to the first input. The second interconnect is coupled to the second input. The first memory cell includes a first cell transistor and a first cell capacitor coupled in series. The first selection transistor is coupled between the first interconnect and the first memory cell. The second memory cell includes a second cell transistor and a second cell capacitor coupled in series. The second selection transistor is coupled between the second interconnect and the second memory cell. A first operation of raising a potential of a gate of the first selection transistor is performed. A second operation of lowering a potential of the first signal is performed after the first operation. A third operation of raising a potential of a gate of the first cell transistor and raising a potential of a gate of the second selection transistor is performed after the second operation.

Embodiments will now be described with reference to the figures. In order to distinguish components having substantially the same function and configuration in an embodiment or over different embodiments from each other, an additional numeral or letter may be added to the end of each reference numeral or letter. In the following description, in an embodiment following an embodiment that is already described, different points from the already described embodiment are mainly described. The entire description of a particular embodiment applies to another embodiment unless an explicit mention is made otherwise, or an obvious elimination is involved.

Each functional block may be implemented as hardware, computer software, or their combination. Some of the functions may be implemented by functional blocks different from those illustrated below. Furthermore, an illustrated functional block may be divided into functional sub-blocks.

The specification and the claims, when mentioning that a particular (first) component is “coupled” to another (second) component, intend to cover both the form of the first component directly coupled to the second component and the form of the first component coupled to the second component via a single or more components which are always or selectively conductive.

### 1. FIRST EMBODIMENT

### 1.1. Structure (Configuration)

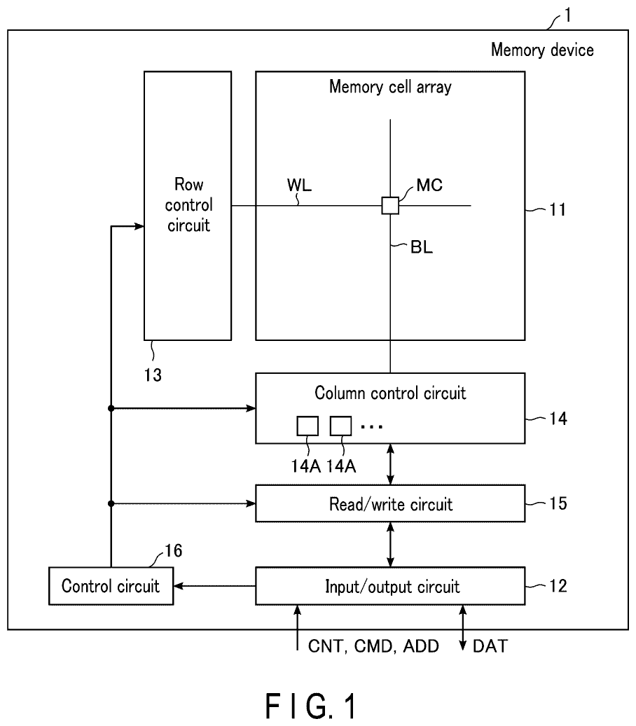

FIG. 1 illustrates functional blocks of a memory device according to a first embodiment. The memory device 1 is a device that stores data. The memory device 1 includes a memory cell array 11, an input/output circuit 12, a row control circuit 13, a column control circuit 14, a read/write circuit 15, and a control circuit 16.

The memory cell array 11 is a functional block that stores data. The memory cell array 11 includes a plurality of memory cells MC. The memory cell MC stores data. Each memory cell MC is associated with a set of rows and columns. The plurality of memory cells MC associated with the same row are coupled to a single word line WL. The plurality of memory cells MC associated with the same column are coupled to a single bit line BL.

The input/output circuit 12 is a circuit that inputs and outputs data and signals. The input/output circuit 12 receives a control signal CNT, a command CMD, address information ADD, and data DAT from the outside of the memory device 1. The input/output circuit 12 outputs the data DAT. The data DAT is write data in the case of data writing in the memory device 1. The data DAT is read data in the case of data reading from the memory device 1.

The row control circuit 13 is a circuit that controls the word line WL. The row control circuit 13 receives the address information ADD from the input/output circuit 12. The row control circuit 13 brings a single word line WL associated with the row specified by the received address information ADD into a selected state. The row control circuit 13 also brings another word line WL into an unselected state based on the received address information ADD.

The column control circuit 14 is a circuit that controls the bit lines BL. The column control circuit 14 receives the address information ADD from the input/output circuit 12. The column control circuit 14 includes a plurality of sense amplifier circuits 14A. During data reading, the sense amplifier circuit 14A amplifies the potential appearing in the bit line BL based on the data stored in the memory cell MC as a data reading target, and generates a read signal (voltage or current). The column control circuit 14 supplies a read signal for the bit line BL specified by the address information ADD to the read/write circuit 15. During data writing, the column control circuit 14 supplies a write signal (voltage or current) based on data to be written to the bit line BL specified by the address information ADD.

The read/write circuit 15 is a circuit that performs control for writing data to the memory cells MC and control for reading data from the memory cells MC. The read/write circuit 15 receives write data from the input/output circuit 12. The read/write circuit 15 supplies a write signal (voltage or current) based on the write data to the column control circuit 14. During data reading, the read/write circuit 15 receives a read signal (voltage or current) based on the state based on the data stored in the memory cell MC to be read from the column control circuit 14. The read/write circuit 15 generates read data based on the read signal and supplies the read data to the input/output circuit 12.

The control circuit 16 is a circuit that controls the operation of the memory device 1. The control circuit 16 receives the command CMD and the control signal CNT from the input/output circuit 12. The control circuit 16 controls the row control circuit 13, the column control circuit 14, and the read/write circuit 15 based on the control instructed by the command CMD and the control signal CNT.

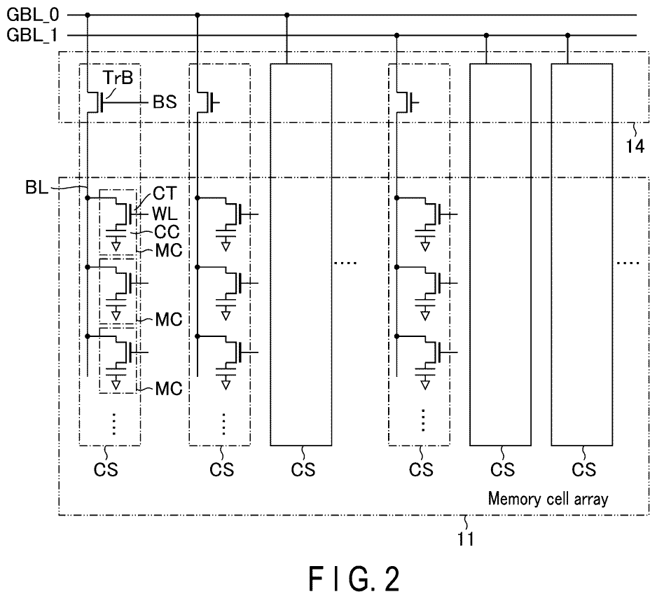

FIG. 2 illustrates some components of the memory device of the first embodiment and coupling of the components. As illustrated in FIG. 2, the memory device 1 includes at least two global bit lines GBL (GBL_0 and GBL_1) and a plurality of cell groups CS. Hereinafter, one of the source and the drain of the transistor may be referred to as a single end of the transistor, and the other may be referred to as the other end of the transistor.

Each cell group CS is coupled to a single global bit line GBL. FIG. 2 illustrates an example in which three cell groups CS are coupled to each global bit line GBL. Each cell group CS includes a single bit line selection transistor TrB, a plurality of memory cells MC, and a single bit line BL.

The bit line selection transistor TrB is coupled between a single global bit line GBL and a single bit line BL. In one example, the bit line selection transistor TrB is an n-type metal oxide semiconductor field effect transistor (MOSFET). The bit line selection transistor TrB receives the bit line selection signal BS at the gate. The plurality of different bit line selection transistors TrB receive the plurality of different bit line selection signals BS, respectively. Two or more bit line selection transistors TrB may receive the common bit line selection signal BS at each of the plurality of gates. In one example, the bit line selection transistor TrB is included in the column control circuit 14. In one example, the bit line selection signal BS is supplied from a circuit in the column control circuit 14, and is based on the control signal and the address information ADD from the control circuit 16.

Each of the plurality of memory cells MC is coupled to the bit line BL at a single end. Each memory cell MC includes a cell transistor CT and a cell capacitor CC. The cell transistor CT and the cell capacitor CC are coupled in series. A node of the cell transistor CT opposite to the cell capacitor CC is coupled to the bit line BL. A node of the cell capacitor CC opposite to the cell transistor CT is coupled to the plate line PL (not illustrated). The plurality of different cell transistors CT are coupled to the plurality of different word lines WL. Two or more cell transistors CT may be coupled to a common word line WL at a plurality of gates thereof.

The cell transistor CT has a set of shape, structure, and/or dimensions substantially the same as or similar to the bit line selection transistor TrB. “Substantially the same” refers to that although intended to be the same, unintended errors may result due to limitations of manufacturing and/or measurement techniques. The cell transistor CT may have a set of shape, structure, and/or dimensions different from those of the bit line selection transistor TrB. In one example, the cell transistor CT and the bit line selection transistor TrB are formed by a common manufacturing process (set of manufacturing steps).

The cell capacitor CC stores data using charge (amount of charge) accumulated at a node coupled to the cell transistor CT. A state of whether or not the node coupled to the cell transistor CT of the cell capacitor CC accumulates charges is associated with a state in which the memory cell MC stores “1” data or “0” data.

The memory device 1 does not need to include a reference cell for determining what data is stored in the memory cell MC as a data reading target. In one example, the memory device 1 does not include a reference cell. In one example, the memory device 1 uses all the memory cells MC except the dummy cell not as a reference cell but as a memory cell that stores data. The dummy cell is formed for forming the memory cell MC having substantially uniform characteristics (dimensions), and in one example, the dummy cell is located at the most end in the region where the memory cell MC is formed.

All the memory cells MC except the dummy cell have substantially the same characteristics. More specifically, in one example, all the memory cells MC except the dummy cell have substantially the same set of shape, structure, and/or dimensions.

The memory cell array 11, the row control circuit 13, and the column control circuit 14 are configured to form a state in which only a single memory cell MC is selected by selecting a single word line WL and a single bit line BL. As long as such a configuration is employed, as described above, two or more bit line selection transistors TrB may receive the common bit line selection signal BS in each of the plurality of gates, and/or two or more cell transistors CT may be coupled to the common word line WL in each of the plurality of gates.

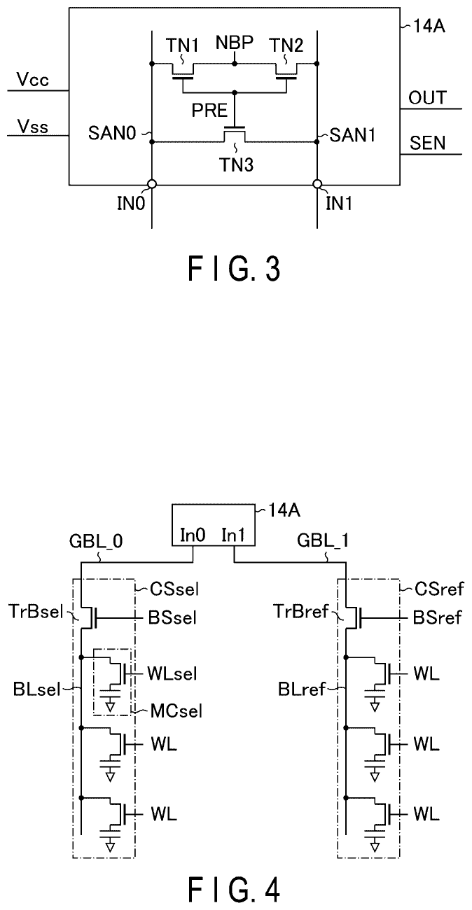

FIG. 3 illustrates some components and coupling of the components of the sense amplifier of the memory device of the first embodiment. As illustrated in FIG. 3, the sense amplifier circuit 14A includes inputs IN0 and IN1 and nodes (interconnects) SAN0 and SAN1. Although not illustrated in FIG. 3, the sense amplifier circuit 14A includes a flip-flop in order to amplify the potential appearing in the bit line BL based on the data stored in the memory cell MC. That is, in one example, an inverter circuit having an output coupled to the node SAN0 and an inverter circuit having an output coupled to the node SAN1 are included. The input and output of one of the two inverter circuits are coupled to the output and input of the other inverter circuit, respectively.

The sense amplifier circuit 14A receives an internal power supply voltage Vcc and the reference voltage. In one example, the reference voltage is the ground voltage Vss, and the following description is based on this example. The sense amplifier circuit 14A receives the enable signal SEN. The sense amplifier circuit 14A is in an operable state while receiving a valid logic (or asserted) enable signal SEN. The sense amplifier circuit 14A, while being in an operable state, raises the higher potential of the potentials of the nodes SAN0 and SAN1 to a certain high potential and lowers the lower potential to a certain low potential. In one example, the high potential has a magnitude equal to the magnitude of the internal power supply voltage Vcc and the low potential has a magnitude equal to the magnitude of the ground voltage Vss. In one example, the valid logic of the enable signal SEN is at a high level.

The input IN0 is coupled to the node SAN0. The input IN1 is coupled to the node SAN1.

The sense amplifier circuit 14A further has a configuration capable of selectively connecting both the nodes SAN0 and SAN1 to the node NBP. In one example, as illustrated in FIG. 3, the sense amplifier circuit 14A includes n-type MOSFETs TN1, TN2, and TN3. The transistor TN1 is coupled between the node SAN0 and the node NBP. The node NBP receives a precharge voltage Vpc. The precharge voltage Vpc has, for example, half the difference between the magnitude of the internal power supply voltage Vcc and the magnitude of the ground voltage Vss, that is, the voltage Vcc/2. The transistor TN1 receives a signal PRE at the gate. In one example, the signal PRE is supplied from the read/write circuit 15.

The transistor TN2 is coupled between the node SAN1 and the node NBP. The transistor TN2 receives the signal PRE at the gate.

The transistor TN3 is coupled between the node SAN0 and the node SAN1. The transistor TN3 receives the signal PRE at the gate.

Either of the transistors TN1 and TN2 may be omitted. The transistor TN3 may be omitted. The transistors TN1, TN2, and TN3 may be included in the column control circuit 14, and may be included outside the sense amplifier circuit 14A.

### 1.2. Operation

FIG. 4 illustrates some components and coupling of the components during data reading of the memory device of the first embodiment. FIG. 4 illustrates a state during data reading from a memory cell MC as a certain data reading target. Hereinafter, the memory cell MC as the data reading target may be referred to as a selected memory cell MCsel. The word line WL coupled to the selected memory cell MCsel may be referred to as a selected word line WLsel. The cell group CS including the selected memory cell MCsel may be referred to as a selected cell group CSsel. The bit line selection transistor TrB in the selected cell group CSsel may be referred to as a selected bit line selection transistor TrBsel. The bit line selection signal BS received by the selected bit line selection transistor TrBsel may be referred to as a selected bit line selection signal BSsel. The bit line BL in the selected cell group CSsel may be referred to as a selected bit line BLsel.

FIG. 4 illustrates an example in which the selected cell group CSsel is coupled to the global bit line GBL_0.

During data reading from the selected memory cell MCsel, a single cell group CS coupled to the global bit line GBL_1 is used for assisting the data reading. Any cell group CS coupled to the global bit line GBL_1 may be used. Hereinafter, the cell group CS used for assistance may be referred to as a reference cell group CSref. The bit line selection transistor TrB in the reference cell group CSref may be referred to as a reference bit line selection transistor TrBref. The bit line selection signal BS received by the reference bit line selection transistor TrBref may be referred to as a reference bit line selection signal BSref. The bit line BL in the reference cell group CSref may be referred to as a reference bit line BLref.

Each bit line BL including the selected bit line BLsel and the reference bit line BLref is maintained at the precharge potential Vpc while not receiving access including data reading from the memory cell MC coupled thereto. The precharge potential Vpc has substantially the same magnitude as that of the precharge voltage Vpc, that is, has a magnitude of Vcc/2.

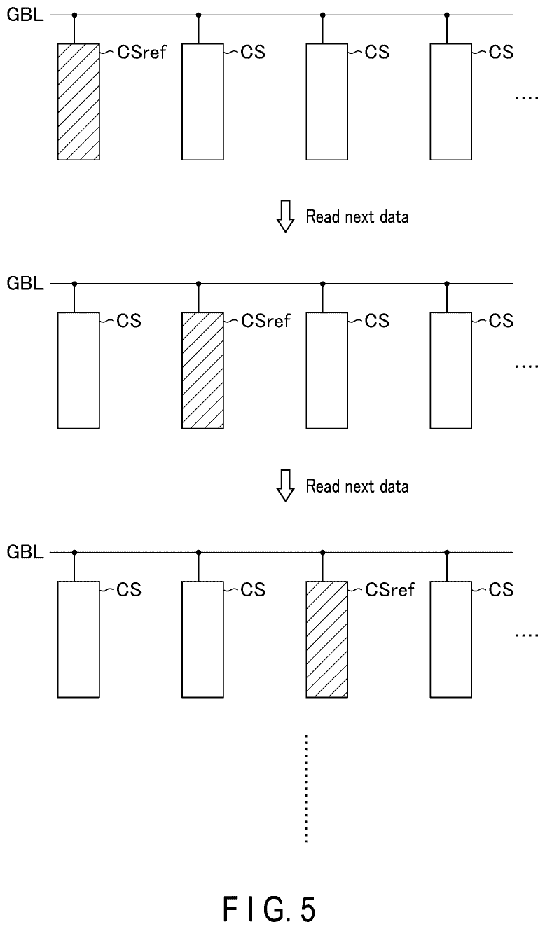

FIG. 5 illustrates several states during data reading of the memory device of the first embodiment along time. As shown in FIG. 5, at each data reading, a cell group CS different from the cell group CS used as the reference cell group CSref in the previous data reading may be used as the reference cell group CSref. In the next data reading subsequent to the previous data reading, the bit line selection transistor TrB different from the previous bit line selection transistor TrB may be turned on as the selected bit line selection transistor TrBsel, or the bit line selection transistor TrB same as the previous bit line selection transistor TrB may be turned on as the selected bit line selection transistor TrBsel. In a case where the bit line selection transistor TrB same as that of the previous time is turned on, a word line WL different from that of the previous time may become the selected word line WLsel, or a word line WL same as that of the previous time may continuously become the selected word line WLsel. In any of these cases, a cell group CS different from the cell group CS used as the reference cell group CSref in the previous data reading can be used as the reference cell group CSref. Note that a different cell group CS is not necessarily used as the reference cell group CSref each time data is read. In one example, during two or more consecutive data reading, a single cell group CS may be used as the reference cell group CSref, and during the next two or more consecutive data reading, the next cell group CS may be used as the reference cell group CSref.

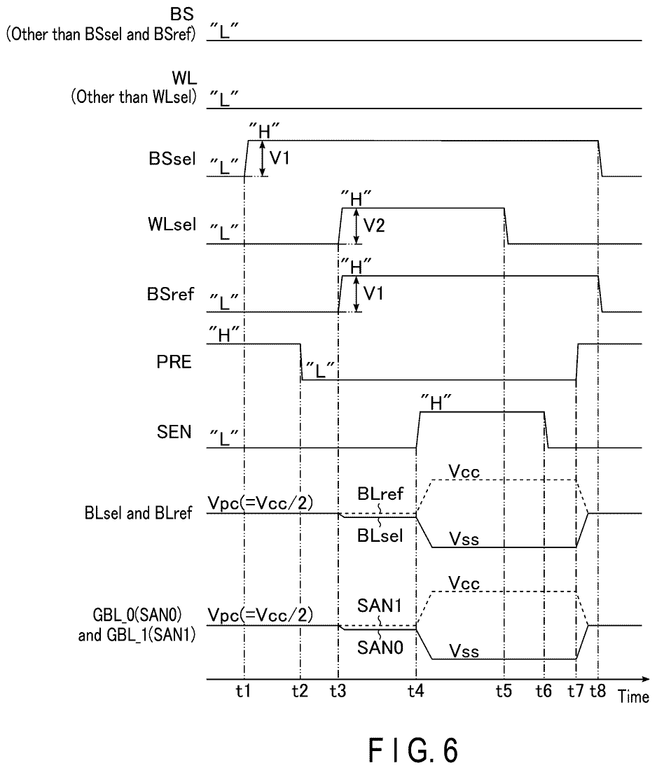

FIG. 6 illustrates potentials of several interconnects and signals during data reading of the memory device of the first embodiment along time. In one example, the data reading illustrated in FIG. 6 starts when the memory device 1 determines to read data from the selected memory cell MCsel based on the command CMD. The data reading illustrated in FIG. 6 is performed in a state in which the connection illustrated in FIG. 4 is made.

As shown in FIG. 6, at the start of the period shown in FIG. 6, the interconnects and signals have potentials described below. The selected bit line selection signal BSsel, the potential of the selected word line WLsel, the reference bit line selection signal BSref, and the enable signal SEN have a low (“L”) level or a low potential. In one example, the low level or low potential has substantially the same magnitude as the magnitude of the ground voltage Vss and is 0 V. The signal PRE has a high (“H”) level.

The potentials of the word lines WL other than the selected word line WLsel continue to have the low level over the period illustrated in FIG. 6. Therefore, the memory cells MC other than the selected memory cell MCsel including the memory cell MC in the reference cell group CSref continue to remain in the off state over the period illustrated in FIG. 6.

The bit line selection signal BS other than the selected bit line selection signal BSsel and the reference bit line selection signal BSref continues to have the low level over the period illustrated in FIG. 6. Therefore, the bit line selection transistors TrB other than the selected bit line selection transistor TrBsel and the reference bit line selection transistor TrBref continue to remain in the off state over the period illustrated in FIG. 6.

Based on the fact that the selected bit line selection signal BSsel has the low level, the selected bit line selection transistor TrBsel is in the off state. Based on the fact that the selected word line WLsel has the low level, the cell transistor CT of the selected memory cell MCsel is in the off state. Based on the fact that the reference bit line selection signal BSref has the low level, the reference bit line selection transistor TrBref is in the off state.

Based on the fact that the signal PRE has the high level, the transistors TN1 and TN2 of the sense amplifier circuit 14A are in an on state, and both the nodes SAN0 and SAN1 are precharged to the precharge potential Vpc (=Vcc/2).

Based on the fact that the enable signal SEN has the low level, the sense amplifier circuit 14A is in an inoperable state, that is, a state in which the potentials of the nodes SAN0 and SAN1 cannot be changed to the internal power supply potential Vcc and the ground potential Vss. The internal power supply potential Vcc is a potential that an interconnect has by receiving the internal power supply voltage Vcc, and has substantially the same magnitude as the internal power supply voltage Vcc. The ground potential Vss is a potential that an interconnect has by receiving the ground voltage Vss, and has substantially the same magnitude as the ground voltage Vss.

As described above with reference to FIG. 4, a bit line BL is maintained at the precharge potential (=Vcc/2) while there is no access to the memory cell MC coupled to the bit line BL. Therefore, at the start of the period shown in FIG. 6, the selected bit line BLsel and the reference bit line BLref have the precharge potential Vpc.

At time t1, the selected bit line selection signal BSsel is set to the high level. As a result, the selected bit line BLsel is coupled to the global bit line GBL_0 and the node SAN0 of the sense amplifier circuit 14A. The high-level potential (the difference between the low-level potential and the high-level potential) of the bit line selection signal BS including the selected bit line selection signal BSsel has a magnitude V1.

A capacitance exists between the gate of the selected bit line selection transistor TrBsel and the selected bit line BLsel. Therefore, in a case where the selected bit line selection signal BSsel is set to the high level, the potential of the selected bit line BLsel and thus the global bit line GBL_0 can increase, and the increase in the potential behaves as noise to the global bit line GBL_0. However, at time t1, since the node SAN0 (global bit line GBL_0) and the node SAN1 (global bit line GBL_1) are precharged, the influence of noise is suppressed.

At time t2, the potential of the signal PRE is set to the low level. As a result, the precharge ends, and the potentials of the nodes SAN0 and SAN1 of the sense amplifier circuit 14A are independent of each other.

At time t3, the potential of the selected word line WLsel is set to the high level. As a result, the cell transistor CT of the selected memory cell MCsel is turned on. As a result, the potential of the selected bit line BLsel has a magnitude based on the data stored in the selected memory cell MCsel, that is, the charge stored in the cell capacitor CC of the selected memory cell MCsel due to charge sharing. FIG. 6 illustrates a case where the selected memory cell MCsel does not store a charge in the cell capacitor CC. The selected bit line BLsel has a potential lower than the precharge potential Vpc. The node SAN0 coupled to the selected bit line BLsel also has the same potential as the selected bit line BLsel. As a result of the charge sharing, the cell capacitor CC of the selected memory cell MCsel loses the stored charge. The high-level potential (the difference between the low-level potential and the high-level potential) of the selected word line WLsel has a magnitude V2.

On the other hand, the reference bit line BLref and the node SAN1 are not coupled to any of the cell capacitors CC and are electrically floating. Therefore, at time t3, charge sharing that occurs in the selected bit line BLsel does not occur. Therefore, the reference bit line BLref and the node SAN1 maintain the same potential after time t3. However, noise (influence of a potential from another interconnect due to a parasitic capacitance) can ride on the reference bit line BLref and the node SAN1.

A capacitance exists between the selected word line WLsel and the selected bit line BLsel. Therefore, when the potential of the selected word line WLsel is set to the high level, the potential of the selected bit line BLsel increases.

At time t3, the reference bit line selection signal BSref is set to the high level. As a result, the reference bit line BLref is coupled to the global bit line GBL_1 and the node SAN1 of the sense amplifier circuit 14A. In one example, the magnitude V1 is substantially the same as the magnitude V2. The magnitude V1 may be different from the magnitude V2.

The control of the reference bit line selection signal BSref to the high level is performed in order to suppress the influence of the increase in the potential of the selected bit line BLsel due to the control of the selected word line WLsel to the high level. Therefore, the control of the reference bit line selection signal BSref to the high level may not be performed at the same timing as the control of the selected word line WLsel to the high level as long as the influence of the increase in the potential of the selected bit line BLsel due to the control of the selected word line WLsel to the high level can be suppressed. In one example, the reference bit line selection signal BSref is set to the high level in accordance with the timing of the increase in the potential of the selected bit line BLsel by the control of the selected word line WLsel to the high level.

At time t4, the enable signal SEN is set to the high level. As a result, the sense amplifier circuit 14A becomes operable. Therefore, the higher potential of the potentials of the nodes SAN0 and SAN1 is raised to the internal power supply potential Vcc, and the lower potential of the potentials of the nodes SAN0 and SAN1 is lowered to the ground potential Vss. In the example illustrated in FIG. 6, the potential of the node SAN0 is lowered to the ground potential Vss, and the potential of the node SAN1 is raised to the internal power supply potential Vcc. The selected bit line BLsel coupled to the node SAN0 also has the ground potential Vss. In addition, the reference bit line BLref coupled to the node SAN1 also has the internal power supply potential Vcc.

In a case where the selected memory cell MCsel does not store charges in the cell capacitor CC, the node SAN1 and the reference bit line BLref have the internal power supply potential Vcc, and the node SAN0 and the selected bit line BLsel have the ground potential Vss. Since the selected bit line BLsel has the ground potential Vss, no charge is stored in the cell capacitor CC of the selected memory cell MCsel, that is, the state before data reading is restored.

In a case where the selected memory cell MCsel stores the charge in the cell capacitor CC, the selected bit line BLsel has the internal power supply potential Vcc, whereby the charge is stored in the cell capacitor CC of the selected memory cell MCsel. That is, the state of the selected memory cell MCsel before data reading is restored.

At time t5, the potential of the selected word line WLsel is set to the low level. As a result, the cell transistor CT of the selected memory cell MCsel is turned off.

At time t6, the potential of the enable signal SEN is set to the low level. As a result, the sense amplifier circuit 14A becomes inoperable.

At time t7, the potential of the signal PRE is set to the high level. As a result, the transistors TN1 and TN2 of the sense amplifier circuit 14A are turned on, and both the nodes SAN0 and SAN1 are precharged to the precharge potential Vpc. In addition, the potential of the selected bit line BLsel coupled to the node SAN0 and the potential of the reference bit line BLref coupled to the node SAN1 also become the precharge potential Vpc.

At time t8, the selected bit line selection signal BSsel is set to the low level. As a result, the selected bit line selection transistor TrBsel is turned off.

At time t8, the potential of the reference bit line selection signal BSref is set to the low level. As a result, the reference bit line selection transistor TrBref is turned off.

### 1.3. Advantages

As described above with reference to FIG. 6, when the potential of the selected word line WLsel is set to the high level, the potential of the selected bit line BLsel increases. This functions as noise on the node SAN0 of the sense amplifier circuit 14A during data reading, and reduces the accuracy of data reading. On the other hand, the following comparative example is conceivable. That is, in the comparative example, a single cell group CS coupled to the global bit line GBL_1 is used as a dedicated cell group (hereinafter, referred to as a reference only cell group) CS for reference. The memory cell MC in the reference only cell group CS is not used to store data, and the cell capacitor CC holds a charge having a magnitude of the precharge potential Vpc (=Vcc/2). When the potential of the selected word line WLsel is set to the high level, the potential of any word line (hereinafter, referred to as a reference only word line) WL in the reference only cell group CS is set to the high level. As a result, the potential of the bit line BL in the reference only cell group CS increases due to the capacity of the memory cell (hereinafter, referred to as a reference only memory cell) MC coupled to the reference only word line WL. Therefore, the influence of the increase in the potential of the selected bit line BLsel is suppressed.

However, since the potential of the reference only word line WL is set to the high level, when the potential of the bit line BL in the reference only cell group CS becomes the internal power supply potential Vcc or the ground potential Vss by the sense amplifier circuit 14A, the potential of the cell capacitor CC of the reference only memory cell MC is shifted from the precharge potential Vpc. Therefore, after the start of the precharge (corresponding to time t7 in FIG. 6 in the first embodiment), a period during which the precharge is performed and the potential of the reference only word line WL is at a high level is provided. By this period, the charge having the magnitude of the precharge potential Vpc is again held in the cell capacitor CC of the reference only memory cell MC, that is, the reference only memory cell MC is restored. However, this period for restoration reduces the speed of reading data from the selected memory cell MCsel. In addition, since a space for providing the reference only cell group CS is required, the size of the memory device of the comparative example is large.

According to the first embodiment, when the potential of the selected word line WLsel is set to the high level, the reference bit line selection signal BSref is set to the high level. A capacitance exists between the interconnect (the gate of the reference bit line selection transistor TrBref) that transmits the reference bit line selection signal BSref and the reference bit line BLref. Therefore, in a case where the reference bit line selection signal BSref is set to the high level, the potential of the reference bit line BLref increases. As a result, the potential of the node SAN1 of the sense amplifier circuit 14A increases. The change (increase) in the potential of the node SAN1 has the same polarity as the change (increase) in the potential of the node SAN0 of the sense amplifier circuit 14A based on the change in the potential of the selected word line WLsel to the high level. Therefore, the increase in the potential of the reference bit line BLref alleviates or cancels out the influence of the operation in the sense amplifier circuit 14A due to the increase in the potential of the selected bit line BLsel due to the increase in the potential of the selected word line WLsel. Therefore, a decrease in data reading accuracy is suppressed. In addition, the suppression of the decrease in the data reading accuracy by the memory device of the first embodiment does not require the reference only cell group and its control as in the comparative example. Therefore, data can be read in a short time.

The amount of increase in the potential of the selected bit line BLsel due to the increase in the potential of the selected word line WLsel depends on the magnitude of the capacitance between the word line WL (gate of the cell transistor CT) and the bit line BL (a single end coupled to the bit line BL of the cell transistor CT). In addition, the amount of increase in the potential of the reference bit line BLref due to the increase in the potential of the reference bit line selection signal BSref depends on the magnitude of the capacitance between the gate of the bit line selection transistor TrB and the bit line BL (a single end coupled to the reference bit line BLref of the bit line selection transistor TrB). Therefore, as the shape, structure, and/or dimensions of the bit line selection transistor TrB are closer to the shape, structure, and/or dimensions of the cell transistor CT, the capacitance of the bit line selection transistor TrB is closer to the capacitance of the cell transistor CT. Therefore, as the shape, structure, and/or dimension of the bit line selection transistor TrB are closer to the shape, structure, and/or dimension of the cell transistor CT, the increase in the potential of the reference bit line BLref based on the increase in the potential of the reference bit line selection signal BSref better suppresses the influence of the increase in the potential of the selected bit line BLsel based on the increase in the potential of the selected word line WLsel.

In addition, the amount of increase in the potential of the selected bit line BLsel due to the increase in the potential of the selected word line WLsel depends on the amount of increase in the potential of the word line WL. The amount of increase in the potential of the reference bit line BLref due to the increase in the potential of the reference bit line selection signal BSref depends on the amount of increase in the potential of the bit line selection signal BS. Therefore, as the amount (magnitude V2) of the increase in the potential of the selected word line WLsel is closer to the amount (magnitude V1) of the increase in the potential of the reference bit line selection signal BSref, the increase in the potential of the reference bit line BLref due to the increase in the potential of the reference bit line selection signal BSref better suppresses the influence of the increase in the potential of the selected bit line BLsel due to the increase in the potential of the selected word line WLsel.

In addition, the memory device 1 of the first embodiment does not require a reference only cell group, and does not require a space for the reference only cell group. Therefore, the memory device 1 is small.

Furthermore, according to the first embodiment, the memory device 1 that operates stably and suppresses a decrease in data reading accuracy is realized. Each bit line BL is maintained at the precharge potential Vpc while not receiving an access including data reading from the memory cell MC coupled to the bit line BL, and is electrically floating by maintaining the bit line selection transistor TrB coupled to the bit line BL in the off state. Therefore, the potential of the bit line BL can unintentionally vary from the precharge potential Vpc. According to the first embodiment, the cell groups CS sequentially function as a reference cell group CSref. Each cell group CS receives the precharge voltage Vpc during the period of functioning as the reference cell group CSref. Therefore, each cell group CS is periodically released from the electrically floating state. Therefore, the memory device 1 operates stably, and thus can read data with high accuracy.

### 1.4. Modification

### 1.4.1. First Modification

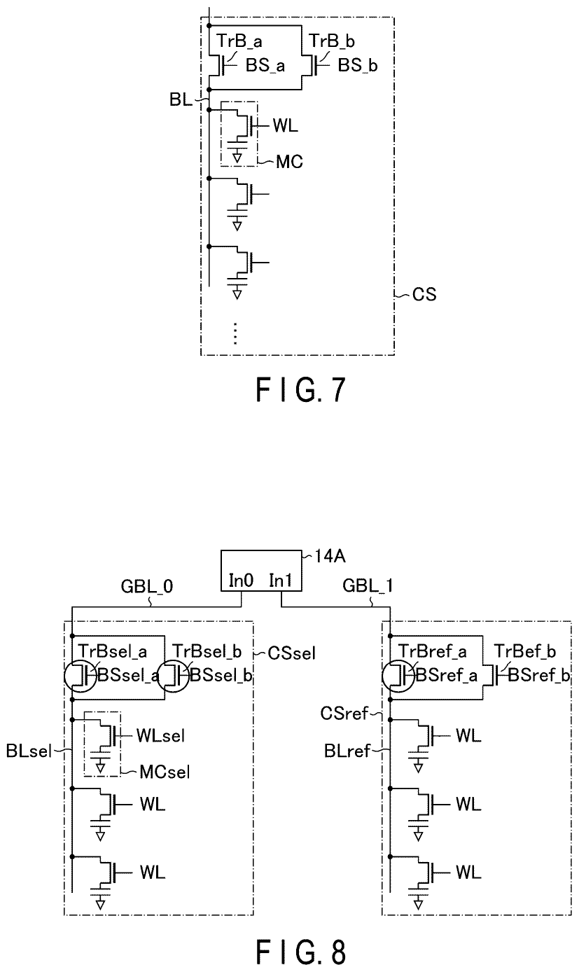

FIG. 7 illustrates some components and coupling of the components of a memory device according to a first modification of the first embodiment. FIG. 7 illustrates components of a cell group CS of the memory device 1 of the first modification and connection of the components. As illustrated in FIG. 7, the cell group CS includes two bit line selection transistors TrB_a and TrB_b. The bit line selection transistors TrB_a and TrB_b are coupled in parallel between a single global bit line GBL and a single bit line BL. The bit line selection transistor TrB_a receives the bit line selection signal BS_a at the gate. The bit line selection transistor TrB_b receives the bit line selection signal BS_b at the gate.

FIG. 8 illustrates a state of the memory device according to the first modification of the first embodiment during data reading. In a case where the cell group CS functions as the selected cell group CSsel, the on-resistance of the bit line selection transistor TrB is preferably low. This is because the speed of access to the selected memory cell MCsel (increase or fall of the potential of the selected bit line BLsel) is high.

On the other hand, in a case where the cell group CS functions as the reference cell group CSref, the bit line selection transistor TrB only needs to be able to suppress the influence of the increase in the selected word line WLsel, and does not necessarily have a low on-resistance.

Based on these requests, as illustrated in FIG. 8, in the selected cell group CSsel, both the bit line selection transistors TrB_a and TrB_b are turned on. On the other hand, in the reference cell group CSref, when the potential of the selected word line WLsel is set to the high level, only one of the bit line selection transistors TrB_a and TrB_b is turned on. FIG. 8 illustrates a case of the bit line selection transistor TrB_a as an example. The bit line selection transistors TrB_a and TrB_b in the on state are surrounded by solid lines.

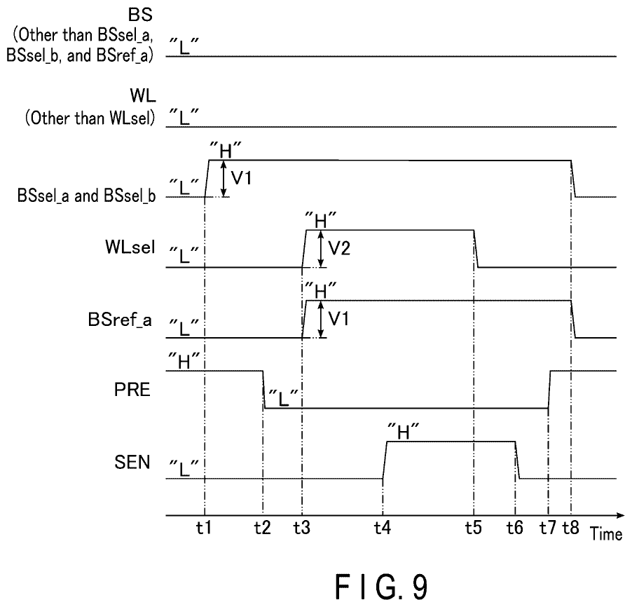

FIG. 9 illustrates potentials of several interconnects and signals during data reading of the memory device according to the first modification of the first embodiment along time. As illustrated in FIG. 9, the selected bit line selection signals BSsel_a and BSsel_b are set to the high level at time t1, and set to the low level at time t8. The reference bit line selection signal BSref_a is set to the high level at time t3 and set to the low level at time t8. The bit line selection signals BS other than the selected bit line selection signals BSsel_a and BSsel_b and the reference bit line selection signal BSref_a maintain the low level over the period illustrated in FIG. 9.

By adjusting the on-resistances and the capacitances of the bit line selection transistors TrB_a and TrB_b, it is possible to individually adjust the characteristics of the operations in the selected cell group CSsel and the reference cell group CSref. That is, it is possible to individually adjust the magnitude of the increase in the potential of the reference bit line BLref due to the increase in the potential of the reference bit line selection signal BSref and the magnitude of the on-resistance of the selected bit line selection transistor TrBsel. As a result, while the influence of the increase in the potential of the selected bit line BLsel is optimally suppressed by the bit line selection transistor TrB_a or TrB_b in the reference cell group CSref, resistance of an optimum magnitude between the global bit line GBL_0 and the selected memory cell MCsel is realized in the selected cell group CSsel.

Each cell group CS may include three or more bit line selection transistors TrB coupled in parallel.

### 1.4.2. Second Modification

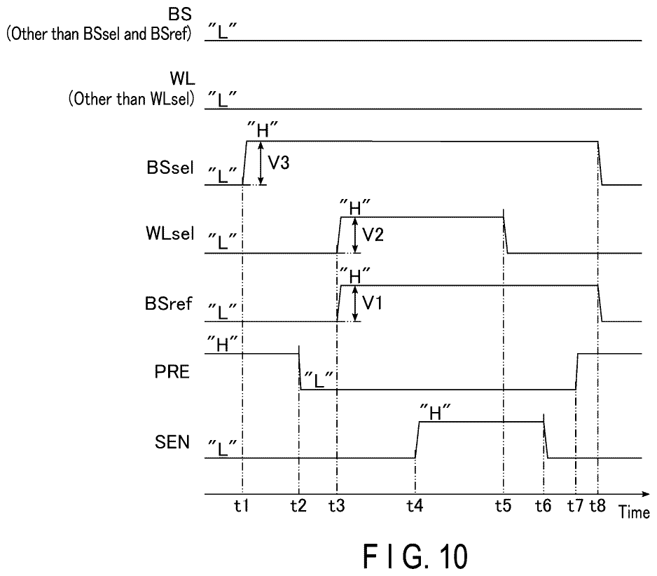

FIG. 10 illustrates potentials of several interconnects and signals during data reading of a memory device according to a second modification of the first embodiment along time.

As illustrated in FIG. 10, the high-level potential (the difference between the low-level potential and the high-level potential) of the selected bit line selection signal BSsel has a magnitude V3. The magnitude V3 is larger than the magnitude V1. For this reason, the on-resistance of the selected bit line selection transistor TrBsel is lower than that in a case where the magnitude V1 is used.

Also in the second modification, the magnitude of the increase in the potential of the reference bit line BLref due to the increase in the potential of the reference bit line selection signal BSref and the magnitude of the on-resistance of the selected bit line selection transistor TrBsel can be adjusted individually. Therefore, the same advantages as those of the first modification can be obtained.

### 1.4.3. Third Modification

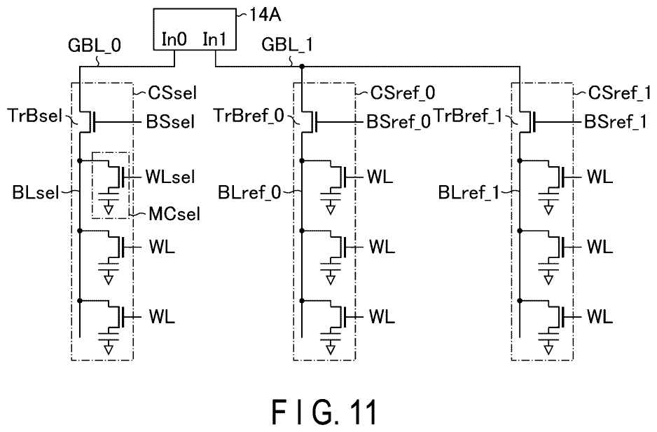

FIG. 11 illustrates some components and coupling of the components during data reading of a memory device according to a third modification of the first embodiment.

As illustrated in FIG. 11, two reference cell groups CSref_0 and CSref_1 are used during data reading from the selected memory cell MCsel. Then, the reference bit line selection signals BSref_0 and BSref_1 of the reference cell groups CSref_0 and CSref_1 are set to the high level when the potential of the selected word line WLsel is set to the high level.

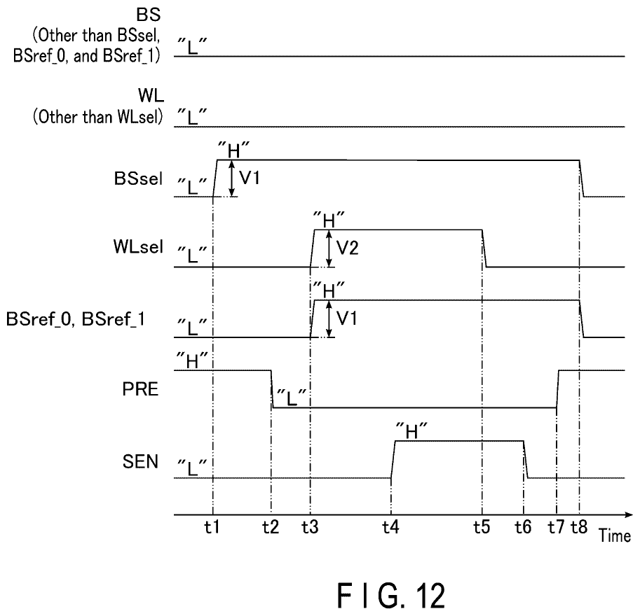

FIG. 12 illustrates potentials of several interconnects and signals during data reading of the memory device according to the third modification of the first embodiment along time. As illustrated in FIG. 12, the reference bit line selection signals BSref_0 and BSref_1 are set to the high level at time t3 and set to the low level at time t8. The bit line selection signals BS other than the selected bit line selection signal BSsel and the reference bit line selection signals BSref_0 and BSref_1 maintain the low level over the period illustrated in FIG. 12.

The amount of increase in the potential of the reference bit line BLref due to the change of the potential of the plurality of reference bit line selection signals BSref to the high level is added. Therefore, the amount of increase in the potential of the reference bit line BLref depends on the number of reference bit line selection signals BSref set to the high level during data reading. Therefore, the amount of increase in the potential of the reference bit line BLref can be adjusted by adjusting the number of reference bit line selection signals BSref set to the high level during data reading. Therefore, also in the third modification, the magnitude of the increase in the potential of the reference bit line BLref due to the increase in the potential of the reference bit line selection signal BSref and the magnitude of the on-resistance of the selected bit line selection transistor TrBsel can be individually adjusted. Therefore, the same advantages as those of the first modification can be obtained.

In addition, according to the third modification, the electrical floating of the bit line BL of each of the two or more cell groups CS is released during a single data reading (reading of data from a single selected memory cell MCsel). Therefore, it is possible to efficiently release the electrical floating of many bit lines BL.

Two or more of the first, second, and third modifications may be combined.

### 2. SECOND EMBODIMENT

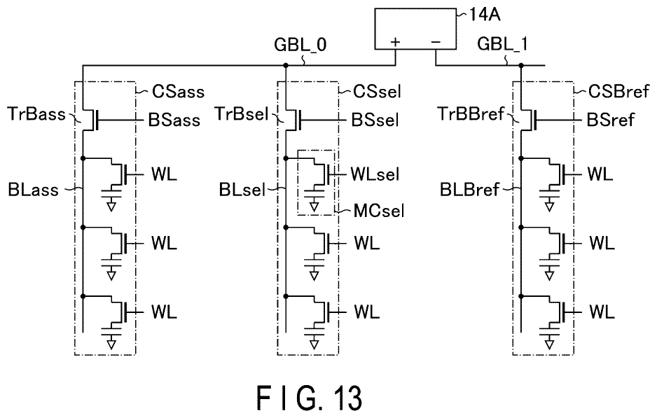

FIG. 13 illustrates some components and coupling of the components during data reading of a memory device of a second embodiment. As illustrated in FIG. 13, a certain cell group CS coupled to the global bit line GBL_0 functions as a selected cell group CSsel. In addition, another cell group CS coupled to the global bit line GBL_0 functions as an auxiliary cell group CSass. The auxiliary cell group CSass has a function of suppressing an increase in the potential of the global bit line GBL_0 due to an increase in the potential of the selected word line WLsel by the reference cell group CSref in the first embodiment. Similarly to that described above for the reference cell group CSref with reference to FIG. 5, in multiple data reading, a cell group CS different from the cell group CS used as the auxiliary cell group CSass in the previous data reading can be used as the auxiliary cell group CSass. Hereinafter, the bit line selection transistor TrB in the auxiliary cell group CSass may be referred to as an auxiliary bit line selection transistor TrBass. The bit line selection signal BS received by the auxiliary bit line selection transistor TrBass may be referred to as an auxiliary bit line selection signal BSass.

A certain cell group CS coupled to the global bit line GBL_1 functions as a reference cell group CSref.

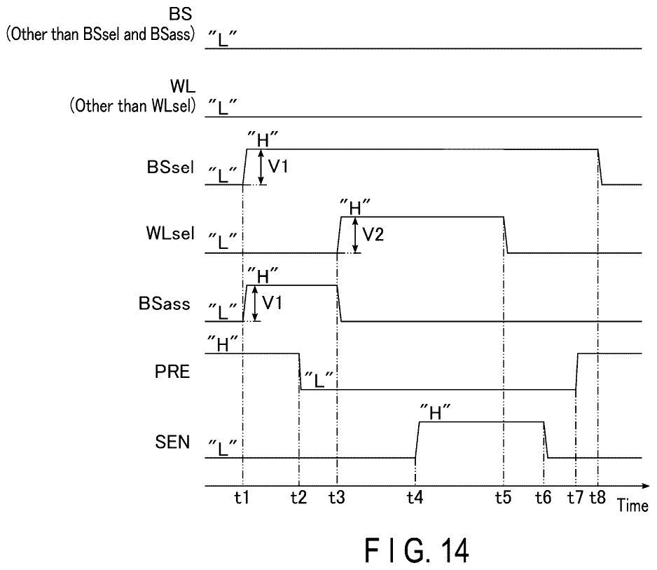

FIG. 14 illustrates potentials of several interconnects and signals during data reading of the memory device of the second embodiment along time. FIG. 14 does not show components coupled with the global bit line GBL_1. Any control can be performed on the reference cell group CSref. In one example, the reference bit line selection signal BSref is maintained at a low level. In another example, the reference bit line selection signal BSref only needs to be set to the potential high level by time t3. A mode in which the reference bit line selection signal BSref is set to the high level at time t3 corresponds to a combination of the second embodiment and the first embodiment.

As illustrated in FIG. 14, at time t1, the potential of the auxiliary bit line selection signal BSass is set to the high level. The change to the high level only needs to be performed before time t2.

At time t3, the auxiliary bit line selection signal BSass is set to the low level. The control of the auxiliary bit line selection signal BSass to the low level is performed to suppress an increase in the potential of the selected bit line BLsel due to the control of the selected word line WLsel to the high level. Therefore, the control of the auxiliary bit line selection signal BSass to the low level does not need to be perfectly identical to the timing of the control of the selected word line WLsel to the high level as long as the increase in the potential of the selected bit line BLsel due to the control of the selected word line WLsel to the high level can be suppressed. In one example, the auxiliary bit line selection signal BSass is set to the low level in accordance with the timing of the increase in the potential of the selected bit line BLsel by the control of the selected word line WLsel to the high level.

According to the second embodiment, the cell group CS coupled to the same global bit line GBL_0 as the selected cell group CSsel functions as the auxiliary cell group CSass, and, when the potential of the selected word line WLsel is set to the high level, the auxiliary bit line selection signal BSass is set to the low level. The change of the auxiliary bit line selection signal BSass to the low level changes the potential of the global bit line GBL_0. The change in the potential of the global bit line GBL_0 has a polarity opposite to the polarity of the noise to the potential of the global bit line GBL_0 due to the change in the potential of the selected word line WLsel to the high level. Therefore, noise to the potential of the global bit line GBL_0 due to the change of the potential of the selected word line WLsel to the high level is suppressed or canceled out. Therefore, a decrease in data reading accuracy is suppressed.

In addition, as in the first embodiment, the suppression of the decrease in the data reading accuracy by the memory device of the second embodiment does not require the reference only cell group and its control as in the comparative example. Therefore, as in the first embodiment, data can be read in a short time.

### 2.1. First Modification

In the first modification, the bit line selection transistor TrB is always maintained in the on state. Then, during data reading, the bit line selection transistor TrB of the selected cell group CSsel is maintained in the on state, and the bit line selection transistors TrB of the cell group CS other than the selected cell group CSsel are turned off.

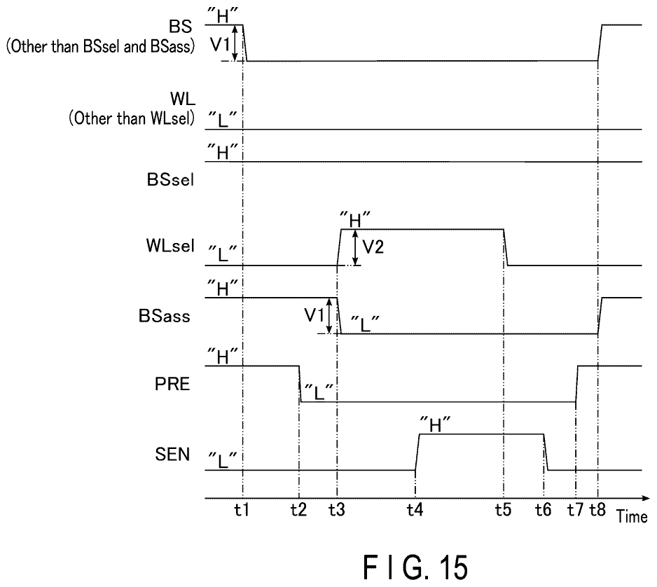

FIG. 15 illustrates potentials of several interconnects and signals during data reading of a memory device according to the first modification of the second embodiment along time. As illustrated in FIG. 15, at the start of the period illustrated in FIG. 15, all the bit line selection signals BS including the selected bit line selection signal BSsel and the auxiliary bit line selection signal BSass have the high level.

The selected bit line selection signal BSsel maintains the high level over the period illustrated in FIG. 15.

At time t1, the bit line selection signals BS other than the selected bit line selection signal BSsel and the auxiliary bit line selection signal BSass are set to the low level.

At time t3, the auxiliary bit line selection signal BSass is set to the low level.

At time t8, the potential of the bit line selection signal BS other than the selected bit line selection signal BSsel is set to the high level.

According to the first modification, even if the bit line selection signal BS is always at the high level, the noise having the opposite polarity to the noise generated on the global bit line GBL_0 by the change in the potential of the selected word line WLsel is generated on the global bit line GBL_0 by the change in the potential of the auxiliary bit line selection signal BSass. Therefore, the same advantages as those of the basic mode of the second embodiment can be obtained.

### 2.2. Second Modification

The second modification corresponds to the application of the first modification of the first embodiment to the second embodiment. That is, the cell group CS has the components and the coupling of the components illustrated in FIG. 7, that is, includes the bit line selection transistors TrB_a and Tr_b. Then, in the selected cell group CSBsel, both the selected bit line selection signals BSBsel_a and BSBsel_b of the selected bit line selection transistors TrBsel_a and TrBsel_b are set to the high level, so that both the selected bit line selection transistors TrBsel_a and TrBsel_b are set to the on state. On the other hand, in the auxiliary cell group CSass, when the potential of the selected word line WLsel is set to the high level, only the potential of a single (for example, BSass_a) of the auxiliary bit line selection signals BSass_a and BSass_b is set to the low level.

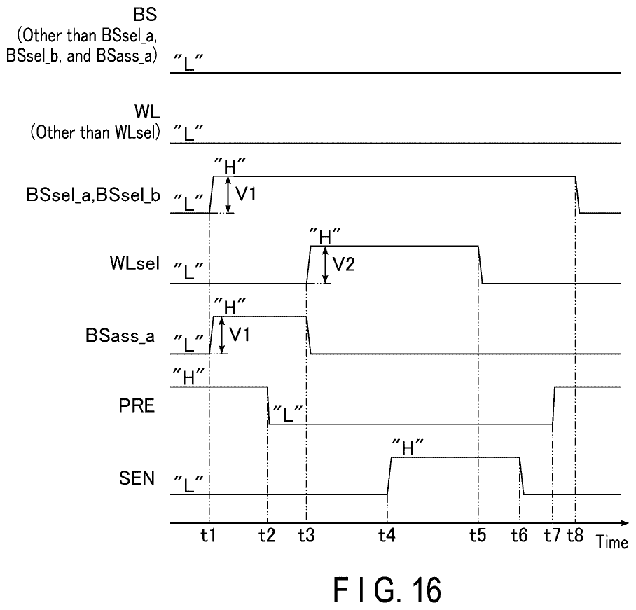

FIG. 16 illustrates potentials of several interconnects and signals during data reading of a memory device according to the second modification of the second embodiment along time. As illustrated in FIG. 16, the selected bit line selection signals BSBsel_a and BSBsel_b are set to the high level at time t1, and set to the low level at time t8. The auxiliary bit line selection signal BSass_a is set to the high level at time t1, and set to the low level at time t3. The bit line selection signals BS other than the selected bit line selection signals BSBsel_a and BSBsel_b and the auxiliary bit line selection signal BSass_a maintain the low level over the period illustrated in FIG. 16.

According to the second modification, the same advantages as the additional advantages according to the first modification of the first embodiment can be additionally obtained.

### 2.3. Third Modification

The third modification corresponds to application of the third modification of the first embodiment to the second embodiment.

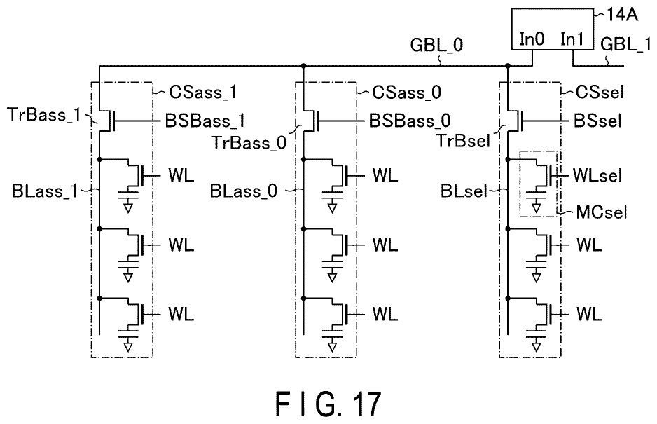

FIG. 17 illustrates some components and coupling of the components during data reading of a memory device according to the third modification of the second embodiment.

As shown in FIG. 17, two auxiliary cell groups CSass_0 and CSass_1 are used during data reading from the selected memory cell MCsel. Then, when the potential of the selected word line WLsel is set to the high level, the auxiliary bit line selection signals BSBass_0 and BSBass_1 of the auxiliary cell groups CSass_0 and CSass_1 are set to the low level.

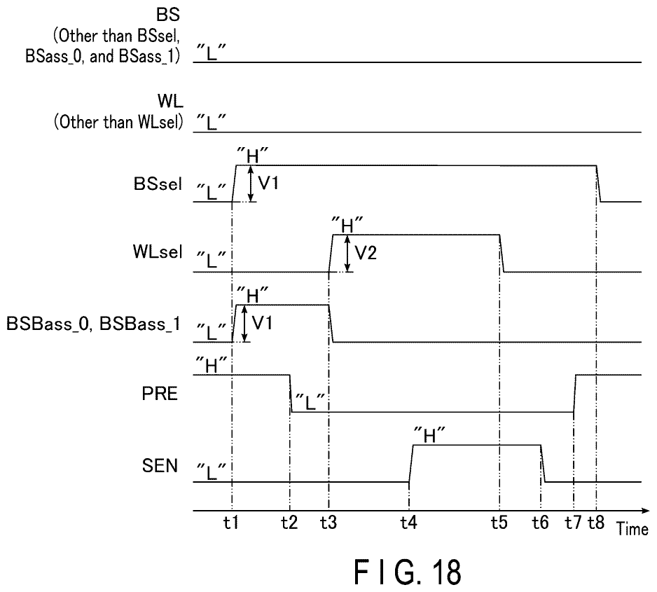

FIG. 18 illustrates potentials of several interconnects and signals during data reading of the memory device according to the third modification of the second embodiment along time. As illustrated in FIG. 18, the auxiliary bit line selection signals BSass_0 and BSass_1 are set to the high level at time t1 and set to the low level at time t3. The bit line selection signals BS other than the selected bit line selection signal BSsel and the auxiliary bit line selection signals BSass_0 and BSass_1 maintain the low level over the period illustrated in FIG. 18.

According to the third modification, the same advantages as the additional advantages according to the third modification of the first embodiment can be additionally obtained.

Two or more of the first, second, and third modifications may be combined. The second modification of the first embodiment may be applied to the second embodiment.

### 3. THIRD EMBODIMENT

The third embodiment corresponds to an excerpt of a part of the first embodiment and the second embodiment. That is, the third embodiment corresponds to a mode in which the control for the reference cell group CSref (particularly, the reference bit line selection transistor TrBref) in the first embodiment or the control for the auxiliary cell group (particularly, auxiliary bit line selection transistor TrBass) in the second embodiment is excluded.

Some components and coupling during data reading of the memory device of the third embodiment are the same as those in FIG. 4 of the first embodiment. However, any control can be performed on the reference cell group CSref. In one example, the reference bit line selection signal BSref is maintained at a low level. In another example, the reference bit line selection signal BSref only needs to be set to the high level by time t3, and is set to the high level at time t1, for example. A mode in which the reference bit line selection signal BSref is set to the high level at time t3 corresponds to the first embodiment.

Alternatively, some components and coupling during data reading of the memory device of the third embodiment are the same as those in FIG. 13 of the second embodiment. However, control for the auxiliary cell group CSass is not performed. A mode in which control for the auxiliary cell group CSass is performed corresponds to the second embodiment.

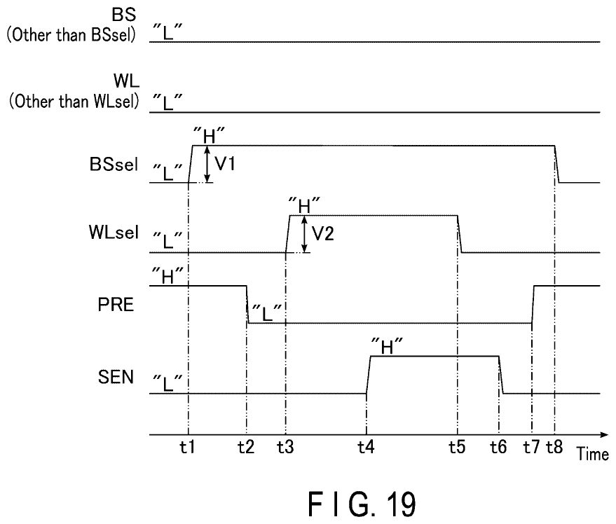

FIG. 19 illustrates potentials of several interconnects and signals during data reading of a memory device according to the third embodiment along time. As illustrated in FIG. 19 and described above with reference to FIG. 6, the signal PRE is set to a high level from the start of the period illustrated in FIG. 19 to time t2.

At time t1, that is, while the signal PRE is at the high level, the selected bit line selection signal BSsel is set to the high level.

At time t3, that is, while the signal PRE is at the low level, the potential of the selected word line WLsel is set to the high level.

According to the third embodiment, as described below, the influence of noise on data reading is suppressed.

A capacitance exists between the gate of the bit line selection transistor TrB and the global bit line GBL. Therefore, when the selected bit line selection signal BSsel on the gate of the bit line selection transistor TrB is set to the high level, the potential of the global bit line GBL can increase, and the increase in the potential behaves as noise to the global bit line GBL.

According to the third embodiment, the control of the selected bit line selection signal BSsel to the high level is performed while the signal PRE is at the high level, that is, while the precharge is performed. Therefore, in the control of the selected bit line selection signal BSsel to the high level, the global bit line GBL_0 receives the precharge voltage Vpc. Therefore, the influence of noise due to an increase in the potential of the global bit line GBL_0 is suppressed.

As described above in the first embodiment, each bit line BL is electrically floating while not being accessed, and the potential of the bit line BL can vary from the precharge potential Vpc. According to the third embodiment, while the precharge is performed, the selected bit line selection signal BSsel is set to the high level, that is, the global bit line GBL_0 and the selected bit line BLsel are coupled. Therefore, in a case where the selected bit line BLsel receives the precharge voltage Vpc at the initial stage of data reading, the variation of the potential while the selected bit line BLsel is electrically floating is eliminated. Therefore, data can be read with high accuracy.

### 3.1. First Modification

In the first modification, as in the first modification of the second embodiment, the bit line selection transistor TrB is always maintained in the on state. That is, the first modification corresponds to an excerpt of a part of the first modification of the second embodiment.

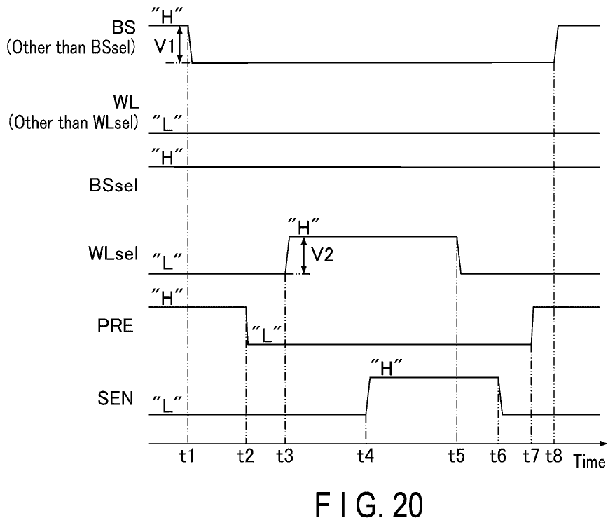

FIG. 20 illustrates potentials of several interconnects and signals during data reading of a memory device according to the first modification of the third embodiment along time. As illustrated in FIG. 20, at the start of the period illustrated in FIG. 20, all the bit line selection signals BS including the selected bit line selection signal BSsel have the high level.

The selected bit line selection signal BSsel maintains the high level over the period illustrated in FIG. 20.

At time t1, that is, while the signal PRE is at the high level, the bit line selection signals BS other than the selected bit line selection signal BSsel, including the reference bit line selection signal BSref, are set to the low level.

When the bit line selection signal BS other than the selected bit line selection signal BSsel on the gate of the bit line selection transistor TrB is set to the low level, the potential of the global bit line GBL can fall due to the capacitance between the gate of the bit line selection transistor TrB and the global bit line GBL, and the fall of the potential behaves as noise to the global bit line GBL_0.

According to the first modification, the control of the bit line selection signals BS other than the selected bit line selection signal BSsel to the low level is performed while the signal PRE is at the high level, that is, while the precharge is performed. By the same principle as the suppression of the influence of noise due to the control of the selected bit line selection signal BSsel to the high level in the basic form of the third embodiment, the influence of noise due to the fall in the potential of the global bit line GBL_0 and the variation of the potential of the selected bit line BLsel are eliminated. Therefore, even in a case where the bit line selection signal BS is always at a high level, data can be read with high accuracy.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a sense amplifier circuit having a first input and a second input;
a plurality of transistors that supply a first potential to the first input and the second input based on a first signal;
a first interconnect coupled to the first input;
a second interconnect coupled to the second input;
a first memory cell including a first cell transistor and a first cell capacitor coupled in series;
a first selection transistor coupled between the first interconnect and the first memory cell;
a second memory cell including a second cell transistor and a second cell capacitor coupled in series; and
a second selection transistor coupled between the second interconnect and the second memory cell, wherein
a first operation of raising a potential of a gate of the first selection transistor is performed,
a second operation of lowering a potential of the first signal is performed after the first operation, and
a third operation of raising a potential of a gate of the first cell transistor and raising a potential of a gate of the second selection transistor is performed after the second operation.

2. The memory device according to claim 1, wherein
a fourth operation of lowering the potential of the gate of the first selection transistor and lowering the potential of the gate of the second selection transistor is performed after the third operation, and
a potential of a gate of the second cell transistor maintains a low level from a start of the first operation to an end of the fourth operation.

3. The memory device according to claim 2, further comprising:
a third selection transistor coupled between the first interconnect and the first memory cell; and
a fourth selection transistor coupled between the second interconnect and the second memory cell, wherein
in the first operation, a potential of a gate of the third selection transistor is raised, and
a potential of a gate of the fourth selection transistor maintains a low level from the start of the first operation to the end of the fourth operation.

4. The memory device according to claim 1, wherein
in the first operation, the potential of the gate of the first selection transistor is raised by a first magnitude,
in the third operation, the potential of the gate of the second selection transistor is raised by a second magnitude, and
the first magnitude is larger than the second magnitude.

5. The memory device according to claim 1, further comprising:
a third memory cell including a third cell transistor and a third cell capacitor coupled in series; and
a third selection transistor coupled between the second interconnect and the third memory cell, wherein
in the third operation, a potential of a gate of the third selection transistor is raised.

6. The memory device according to claim 1, wherein
the first cell capacitor holds one of a first amount of charge and a second amount of charge determined based on data stored in the first memory cell, and
the second cell capacitor holds one of a third amount of charge and a fourth amount of charge determined based on data stored in the second memory cell.

7. The memory device according to claim 1, further comprising:
a fourth memory cell including a fourth cell transistor and a fourth cell capacitor coupled in series;
a fifth selection transistor coupled between the first interconnect and the fourth memory cell;
a fifth memory cell including a fifth cell transistor and a fifth cell capacitor coupled in series; and
a sixth selection transistor coupled between the second interconnect and the fifth memory cell, wherein
a fifth operation of raising a potential of a gate of the fourth cell transistor and raising a potential of a gate of the sixth selection transistor is performed after the third operation.

8. The memory device according to claim 1, further comprising:
a fourth memory cell including a fourth cell transistor and a fourth cell capacitor coupled in series, the fourth memory cell being coupled to the first interconnect via the first selection transistor;
a fifth memory cell including a fifth cell transistor and a fifth cell capacitor coupled in series; and
a fifth selection transistor coupled between the second interconnect and the fifth memory cell, wherein
a fifth operation of raising the potential of the gate of the first cell transistor or a potential of a gate of the fourth cell transistor and raising a potential of a gate of the fifth selection transistor is performed after the third operation.

9. A memory device comprising:
a sense amplifier circuit having a first input and a second input;
a first interconnect coupled to the first input;
a second interconnect coupled to the second input;
a first memory cell including a first cell transistor and a first cell capacitor coupled in series;
a first selection transistor coupled between the first interconnect and the first memory cell;
a second memory cell including a second cell transistor and a second cell capacitor coupled in series; and
a second selection transistor coupled between the first interconnect and the second memory cell; wherein
a first operation of raising a potential of a gate of the first cell transistor and lowering a potential of a gate of the second selection transistor is performed.

10. The memory device according to claim 9, wherein a second operation of raising a potential of a gate of the first selection transistor and a third operation of raising the potential of the gate of the second selection transistor are performed before the first operation.

11. The memory device according to claim 10, wherein
a fourth operation of lowering the potential of the gate of the first selection transistor is performed after the first operation, and
a potential of a gate of the second cell transistor maintains a low level from a start of the second operation to the fourth operation.

12. The memory device according to claim 11, further comprising:
a third selection transistor coupled between the first interconnect and the first memory cell; and
a fourth selection transistor coupled between the first interconnect and the second memory cell, wherein
in the second operation, a potential of a gate of the third selection transistor is raised, and
a potential of a gate of the fourth selection transistor maintains a low level from the start of the second operation to an end of the fourth operation.

13. The memory device according to claim 9, further comprising:
a third memory cell including a third cell transistor and a third cell capacitor coupled in series; and
a third selection transistor coupled between the first interconnect and the third memory cell, wherein
in the first operation, a potential of a gate of the third selection transistor is lowered.

14. The memory device according to claim 9, wherein
the first cell capacitor holds one of a first amount of charge and a second amount of charge determined based on data stored in the first memory cell, and
the second cell capacitor holds one of a third amount of charge and a fourth amount of charge determined based on data stored in the second memory cell.

15. The memory device according to claim 9, further comprising:
a fourth memory cell including a fourth cell transistor and a fourth cell capacitor coupled in series;
a fifth selection transistor coupled between the first interconnect and the fourth memory cell;
a fifth memory cell including a fifth cell transistor and a fifth cell capacitor coupled in series; and
a sixth selection transistor coupled between the first interconnect and the fifth memory cell, wherein
a fifth operation of raising a potential of a gate of the fourth cell transistor and lowering a potential of a gate of the sixth selection transistor is performed after the first operation.

16. The memory device according to claim 9, further comprising:
a fourth memory cell including a fourth cell transistor and a fourth cell capacitor coupled in series, the fourth memory cell being coupled to the first interconnect via the first selection transistor;
a fifth memory cell including a fifth cell transistor and a fifth cell capacitor coupled in series; and
a fifth selection transistor coupled between the first interconnect and the fifth memory cell; wherein
a fifth operation of raising the potential of the gate of the first cell transistor or a potential of a gate of the fourth cell transistor and lowering a potential of a gate of the fifth selection transistor is performed after the first operation.

17. The memory device according to claim 9, further comprising:
a sixth memory cell including a sixth cell transistor and a sixth cell capacitor coupled in series; and
a seventh selection transistor coupled between the first interconnect and the sixth memory cell; wherein
a sixth operation of lowering a potential of a gate of the seventh selection transistor is performed before the first operation, and
a seventh operation of raising the potential of the gate of the second selection transistor and raising the potential of the gate of the seventh selection transistor is performed after the first operation.

18. The memory device according to claim 17, wherein a potential of a gate of the first selection transistor maintains a high level from a start of the sixth operation to an end of the seventh operation.

19. A memory device comprising:
a sense amplifier circuit having a first input and a second input;
a plurality of transistors that supply a first potential to the first input and the second input;
a first interconnect coupled to the first input;
a second interconnect coupled to the second input;
a first memory cell including a first cell transistor and a first cell capacitor coupled in series;
a first selection transistor coupled between the first interconnect and the first memory cell;
a second memory cell including a second cell transistor and a second cell capacitor coupled in series; and
a second selection transistor coupled between the second interconnect and the second memory cell, wherein
a potential of gates of the transistors maintains a high level over a first period,
a potential of a gate of the first selection transistor has a high level at a first time during the first period, and
a potential of a gate of the first cell transistor is raised at a second time after the first period.

20. The memory device according to claim 19, wherein the potential of the gate of the first selection transistor is set to a high level at the first time.

21. The memory device according to claim 19, wherein the potential of the gate of the first selection transistor maintains a high level until a third time after the second time.

22. The memory device according to claim 19, wherein
the gates of the transistors receive a first signal,
a potential of the first signal is raised at a fourth time after the second time, and
the potential of the gate of the first selection transistor is lowered after the fourth time.

23. The memory device according to claim 19, further comprising:
a third memory cell including a third cell transistor and a third cell capacitor coupled in series; and
a third selection transistor coupled between the first interconnect and the third memory cell; wherein
a potential of a gate of the third selection transistor is lowered at a fifth time during the first period.

24. The memory device according to claim 23, wherein
the gates of the transistors receive a first signal,
a potential of the first signal is raised at a sixth time after the second time, and
the potential of the gate of the third selection transistor is raised after the sixth time.
